(19) United States
(12) Patent Application Publication
(10) Pub. No.: US 2011/0206910 A1
(43) Pub. Date: Aug. 25, 2011

(54) WIRING SUBSTRATE AND METHOD FOR MANUFACTURING THE SAME, AND METHOD FOR DISASSEMBLING WIRING SUBSTRATE

(75) Inventor: Takashi IWAMOTO, Urayasu-shi (JP)

(73) Assignee: EMPIRE TECHNOLOGY DEVELOPMENT LLC, Wilmington, DE (US)

(21) Appl. No.: 12/962,980

(22) Filed: Dec. 8, 2010

(30) Foreign Application Priority Data
Feb. 24, 2010 (JP) 2010-038300

(51) Int. Cl. B32B 7/06; H05K 3/02

(52) U.S. Cl. 428/200; 428/202; 427/98.5

(57) ABSTRACT

Embodiments provide a wiring substrate that allows a wire to be released from an insulating material after use, a method for manufacturing the wiring substrate, and a method for disassembling the wiring substrate. A wiring substrate includes a release layer formed between an insulating material and a wire. The release layer is configured to reduce an a strength of adhesion between the wire and the insulating layer when disassembling or recycling the wiring substrate.

### CROSS-REFERENCE TO RELATED APPLICATIONS

This application claims priority to Japanese Patent Application No. 2010-038300, filed on Feb. 24, 2010, which is incorporated herein by reference in its entirety.

### TECHNICAL FIELD

Embodiments disclosed herein relate to a wiring substrate, a method for manufacturing the wiring substrate, and a method for disassembling the wiring substrate.

### BACKGROUND

In various types of electronic equipment such as mobile phones and IC cards, a single-layer or multilayer wiring substrate is used. An electronic device such as an IC chip is mounted on a surface of the wiring substrate or inside the wiring substrate. Metal such as aluminum or copper is used for wires on the wiring substrate. (see, for example, Japanese Patent Laid-Open No. 2010-28107).

In view of global enhanced environmental consciousness and in consideration of the environment, recycling has become an important aspect for wiring substrates and also for electronic equipment with a wiring substrate mounted therein. There is a demand for a wiring substrate from which wires can be released so as to allow wiring metal to be recovered.

However, the surfaces of the wires or insulating materials included in the wiring substrate normally undergo a roughening treatment. Thus, the wire and the insulating material adhere firmly to each other. Releasing the wire from the insulating material is very difficult. Moreover, an epoxy resin or a polyimide resin generally used as the insulating material is a thermosetting resin and has no melting point. Hence, when directly heated, the insulating material is only carbonized. This makes releasing the metal from the insulating material very difficult. Furthermore, in a wiring substrate in which a fire-retardant resin is used as an insulating material, releasing the metal from the insulating material by thermal treatment is more difficult.

It is thus desirable to provide a wiring substrate that allows the wire to be easily released from the insulating material after use, a method for manufacturing the wiring substrate, and a method for disassembling the wiring substrate.

### BRIEF SUMMARY

A wiring substrate according to embodiments disclosed herein includes an insulating material, a wire formed on the insulating material, and a release layer formed between the insulating material and the wire and containing metal carbonate or metal hydrogen carbonate.

According to some embodiments disclosed herein, when the wiring substrate is heated to a temperature equal to or higher than the thermal decomposition temperature of the metal carbonate or metal hydrogen carbonate contained in the release layer formed between the insulating material and the wire, the metal carbonate or metal hydrogen carbonate is thermally decomposed so that the wire can be easily released from the insulating material. The thermal decomposition of the metal carbonate or metal hydrogen carbonate generates carbon dioxide. Thus, a gas space is formed at the interface between the insulating material and the wire. This allows the wire to be easily released from the insulating material. Gas resulting from the thermal decomposition is carbon dioxide, which is harmless and inactive. Hence, the wiring material can be safely recovered.

For example, the metal carbonate may be magnesium carbonate, thallium carbonate, silver carbonate, copper carbonate, lead carbonate, zinc carbonate, iron carbonate, or cobalt carbonate. These inorganic metal carbonates have been confirmed to be thermally decomposable.

For example, the metal hydrogen carbonate may be sodium hydrogen carbonate or potassium hydrogen carbonate. These inorganic metal hydrogen carbonates have been confirmed to be thermally decomposable.

Furthermore, a wiring substrate according some embodiments disclosed herein includes a first insulating material, a wire formed on the first insulating material, a second insulating material stacked on the first insulating material and the wire, and a release layer formed between the first insulating material and the wire or between the second insulating material and the wire and containing metal carbonate or metal hydrogen carbonate.

Moreover, a wiring substrate according to some embodiments disclosed herein includes a first insulating material, a wire formed on the first insulating material, a second insulating material stacked on the first insulating material and the wire, a release layer formed between the first insulating material and the wire or between the second insulating material and the wire and containing metal carbonate formed of magnesium carbonate, thallium carbonate, silver carbonate, copper carbonate, lead carbonate, zinc carbonate, iron carbonate, or cobalt carbonate, or metal hydrogen carbonate formed of sodium hydrogen carbonate or potassium hydrogen carbonate.

Additionally, a method for manufacturing a wiring substrate according to some embodiments disclosed herein includes forming a release layer containing metal carbonate or metal hydrogen carbonate, on an insulating material and forming a wire on the release layer.

Moreover, a method for disassembling a wiring substrate according to some embodiments disclosed herein includes thermally treating a wiring substrate including an insulating material, a wire formed on the insulating material, and a release layer formed between the insulating material and the wire and containing metal carbonate or metal hydrogen carbonate, to thermally decompose the release layer, and releasing the wire from the insulating material.

### BRIEF DESCRIPTION OF THE FIGURES

FIG. 1 is a sectional view showing an illustrative example of a wiring substrate;

FIG. 2 is a sectional view showing an illustrative example of a process of manufacturing a wiring substrate;

FIG. 3 is a sectional view showing the process of manufacturing a wiring substrate;

FIG. 4 is a sectional view showing the process of manufacturing a wiring substrate;

FIG. 5 is a sectional view showing an illustrative example of a wiring substrate;

FIG. 6 is a sectional view showing an illustrative example of a process of manufacturing a wiring substrate;

FIG. 7 is a sectional view showing the process of manufacturing a wiring substrate;

FIG. 8 is a sectional view showing the process of manufacturing a wiring substrate;

FIG. 9 is a sectional view showing the process of manufacturing a wiring substrate;

FIG. 10 is a sectional view showing the process of manufacturing a wiring substrate;

FIG. 11 is a sectional view showing the process of manufacturing a wiring substrate; and

FIG. 12 is a sectional view showing an illustrative example of wiring substrate.

### DETAILED DESCRIPTION

Embodiments disclosed herein will be described below with reference to the Figures. In the Figures, the same components are denoted by the same reference numerals, and duplicate descriptions are omitted. Furthermore, positional relations such as top and bottom and right and left are based on the illustrated positional relations unless otherwise specified. Moreover, the scaling of the Figures is not limited to the illustrated one. In addition, the following embodiments are examples for description of the present disclosure, and the present disclosure is not intended to be limited to the embodiments disclosed herein. Moreover, many variations may be made to the embodiments disclosed herein without departing from the spirits of the present disclosure.

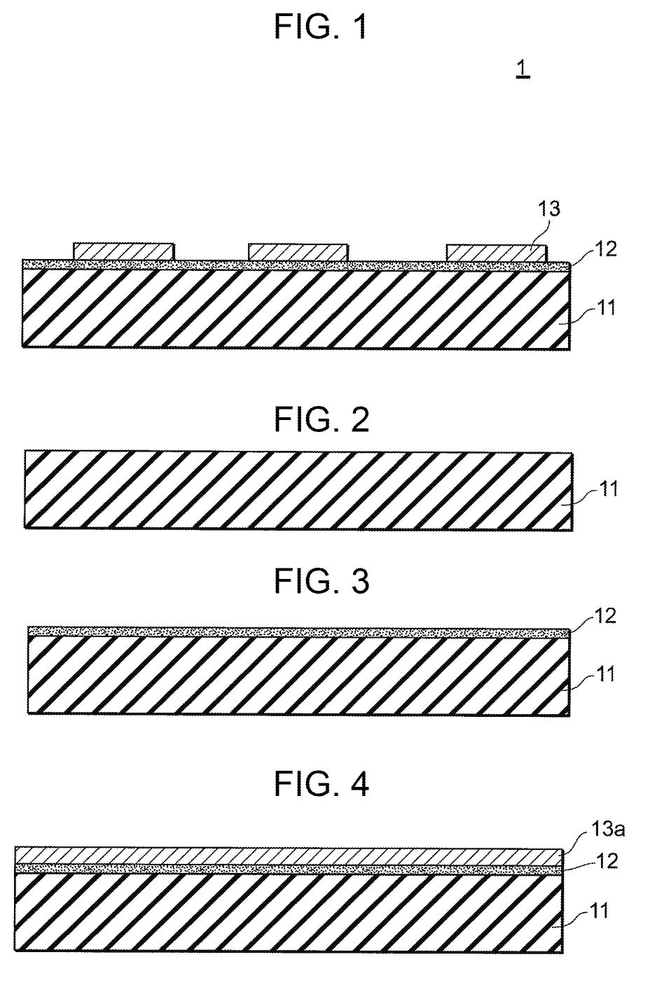

FIG. 1 is a sectional view showing an illustrative example of a wiring substrate 1. The wiring substrate 1 includes an insulating material 11, a release layer 12 formed on the insulating material 11, and a wire 13 formed on the release layer 12. In an area not shown in the drawings, an electronic device may be mounted on a surface of the wiring substrate 1 or inside the wiring substrate 1.

The insulating material 11 is formed of, by way of example only, a resin insulating material or an inorganic insulating material. The following may be used as the resin insulating material: glass epoxy resin, polyimide, a fluorine resin such as polytetrafluoroethylene, polyurethane, polyvinylidene chloride, polyvinyl chloride, polyethylene, amilan, or polypropylene. Furthermore, silicon nitride, silicon dioxide, or the like may be used as the inorganic insulating material.

The release layer 12 may contain metal carbonate or metal hydrogen carbonate. The release layer 12 may be, for example, formed of metal carbonate or metal hydrogen carbonate. Examples of metal carbonate that is thermally decomposable at a predetermined temperature include magnesium carbonate (thermal decomposition temperature: 600° C.), thallium carbonate (thermal decomposition temperature: 272° C.), silver carbonate (thermal decomposition temperature: 220° C.), copper carbonate (thermal decomposition temperature: 220° C.), lead carbonate (thermal decomposition temperature: 315° C.), zinc carbonate (thermal decomposition temperature: 150° C.), iron carbonate (thermal decomposition temperature: 200° C.), and cobalt carbonate (thermal decomposition temperature: 350° C.). Examples of metal hydrogen carbonate that is thermally decomposable at a predetermined temperature include sodium hydrogen carbonate (thermal decomposition temperature: 270° C.) and potassium hydrogen carbonate (thermal decomposition temperature: between 100° C. and 200° C.)

Examples of metal carbonate or metal hydrogen carbonate that resist a reflow temperature (about 260° C.) used in the manufacture of the wiring substrate include thallium carbonate, magnesium carbonate, lead carbonate, cobalt carbonate, iron carbonate, and sodium hydrogen carbonate. Magnesium carbonate may be used to improve heat resistance.

The wire 13 may be formed of a metal or an alloy, for example, copper. However, besides copper, aluminum, platinum, gold, silver, palladium, tin, nickel, chromium, or the like may be used as the wire 13.

A metal foil may be used as the wire 13. In some embodiments, the metal foil is formed of, for example, copper, aluminum, platinum, gold, silver, tin, iron, nickel, cobalt, chromium, zinc, duralumin, or stainless. The thickness of the metal foil is, by way of example only, at most 200 μm in some embodiments.

Examples of the electronic device mounted on the surface of the wiring substrate 1 or inside the wiring substrate include a passive element such as a capacitor or a resistive element, and an active element such as an Integrated Circuit (IC) chip. Alternatively, such an electronic device may be an image sensor such as a Charge Coupled Device (CCD) sensor or a Complimentary Metal Oxide Semiconductor (CMOS) sensor or a display element such as a liquid crystal display element.

A method for manufacturing the above-described wiring substrate will be described with reference to FIG. 2 through FIG. 4. First, as shown in FIG. 2, the insulating material 11 is prepared. For example, a prepreg including a glass cloth impregnated with an epoxy resin or a resin film such as polyimide is used as the insulating material 11.

Then, as shown in FIG. 3, a release layer 12 containing metal carbonate or metal hydrogen carbonate is formed on the insulating material 11. For example, powder of an inorganic metal carbonate such as magnesium carbonate is dispersed in a solvent such as water. The insulating material 11 is then coated with the solvent and the solvent dries on the insulating material 11. The powder used may be the inorganic metal carbonate proper. However, the surface of the inorganic metal carbonate may be covered with a resin such as an epoxy resin or polyimide by a spray drying method or the like to form microcapsules. By way of example only, tubular micropowder manufactured by Nittetsu Mining Co., Ltd. may be used as the magnesium carbonate powder.

Then, as shown in FIG. 4, a metal layer 13a is formed on the release layer 12. For example, a copper foil is thermocompression-bonded to the release layer 12. To improve the adhesion of the copper foil to the release layer 12, for example, a copper foil with its surface roughened may be used. Alternatively, the surface of the release layer 12 may be roughened by etching or the like. Besides the thermocompression bonding of the metal foil, electroless plating or sputtering may be used to form the metal layer 13a.

The metal layer 13a is patterned to form a wire 13 (see FIG. 1). For example, a resist is coated on the metal layer 13a and then exposed and developed to form a resist pattern. The metal layer 13a exposed from the resist pattern is etched. Finally, the resist pattern is removed. A method for forming a pattern of the wire 13 is not limited to the above-described subtract method (the method of forming a wire by removing the unwanted portion of the metal layer with the required portion thereof left). For example, an additive method may be used. If the additive method is used, then for example, a resist is coated on the release layer 12 and then exposed and developed to form a resist pattern. The entire resultant surface is then plated with a metal layer. Then, the resist pattern and the metal layer deposited on the resist pattern are removed.

For example, an electronic device such as an IC chip may be mounted on the surface of the wiring substrate 1, though this is not shown in the drawings. For example, the IC chip may be mounted face down (the IC chip is mounted with its terminal surface directed toward the wiring board) on the wiring substrate 1 by thermocompression-bonding the IC chip and the wiring substrate 1 to each other with an anisotropic conductive film interposed between a terminal surface of the IC chip and the wiring substrate 1. Alternatively, the IC chip may be mounted face up (the IC chip is mounted so that its surface opposite to the terminal surface is directed toward the wiring board) on the wiring substrate 1. In this example, the surface of the IC chip opposite to the terminal surface may be secured on the wiring substrate 1 with an adhesive. The terminal surface of the IC chip may then be electrically connected to the wiring substrate 1 by wire bonding.

When the wiring substrate according to an embodiment is heated to a temperature equal to or higher than the thermal decomposition temperature of the metal carbonate or metal hydrogen carbonate contained in the release layer 12, for example after use of the wiring substrate or when the wiring substrate is ready for recycling or disposal, the metal carbonate or metal hydrogen carbonate is thermally decomposed to generate carbon dioxide. Thus, a gas space is formed between the insulating material 11 and the wire 13. This allows the strength of the adhesion of the wire 13 to the insulating material 11 to be sharply reduced. As a result, the wire 13 can be easily released from the insulating material 11.

Metal carbonate or metal hydrogen carbonate may be selected as a material for the release layer 12. The metal carbonate or metal hydrogen carbonate has a thermal decomposition temperature lower than a thermal treatment temperature used for recycling. For example, when the thermal treatment temperature is at least 600° C., magnesium carbonate may be used as the release layer 12. In this example, when the wiring substrate 1 is heated at 600° C. or higher after the electronic device is separated from the wiring substrate 1, carbon dioxide is generated between the insulating material 11 and the wire 13. The high temperature causes the carbon dioxide to expand and generate a gas pressure that acts to peel off the insulating material 11 from the wire 13 or to separate the insulating material 11 and the wire 13 from each other. Thus, after or during the heating treatment, the wire 13 can be released from the insulating material 11. Hence, waste components resulting mainly from the insulating material can be separated from waste components resulting mainly from the wiring metal material, allowing the subsequent recovery process to be easily and economically achieved. However, embodiments of the disclosure are not limited to the recycling method.

As described above, in some embodiments of the wiring substrate, the presence of the release layer 12 containing the metal carbonate or metal hydrogen carbonate contributes to increasing the efficiency of a metal recovery treatment in the recycling or disposal of the wiring substrate. The release layer 12 can be formed simply by coating insulating layer with the metal carbonate or metal hydrogen carbonate. This prevents a possible increase in recycling costs.

Furthermore, the gas generated from the metal carbonate or metal hydrogen carbonate by thermal decomposition is carbon dioxide, which is harmless. Thus, a wiring substrate that can be safely disassembled and/or recycled can be provided. Additionally, the use of magnesium carbonate (thermal decomposition temperature: 600° C.), which has relatively high heat resistance, serves to provide a wiring substrate that exhibits high heat resistance and improved reliability during normal use.

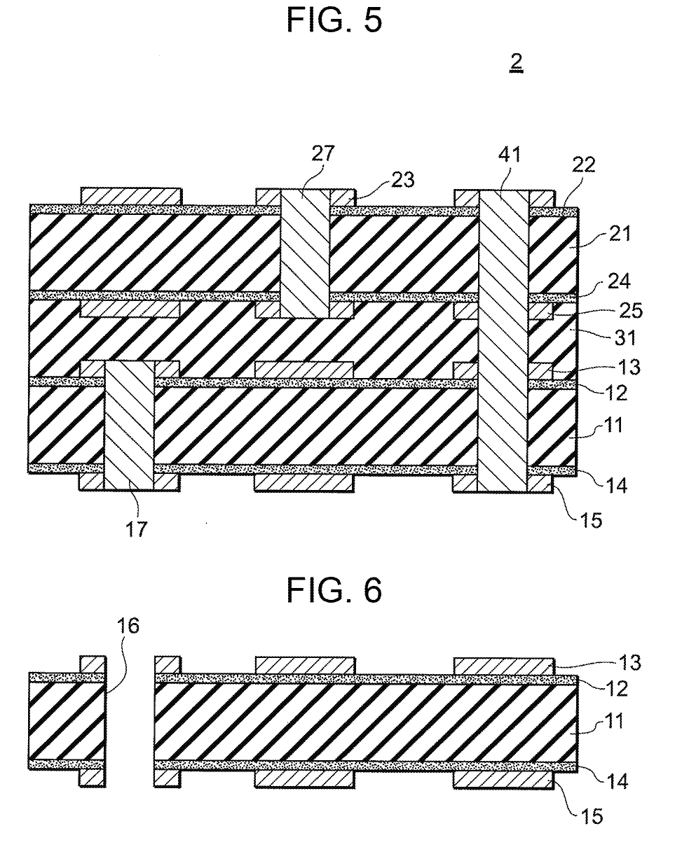

An embodiment relates to a wiring substrate with at least two layers of wires. FIG. 5 is a sectional view showing a wiring substrate 2 according to the second embodiment. The wiring substrate 2 includes a stack of insulating materials 11, 21, and 31. Release layers 12 and 14 are formed on the respective opposite surfaces of the insulating material 11. A wire 13 is formed on the release layer 12. A wire 15 is formed on the release layer 14. A via 17 is formed through the insulating material 11 to connect the wires 13 and 15 on the respective opposite surfaces of the insulating material 11 together.

Release layers 22 and 24 are formed on the respective opposite surfaces of the insulating material 21. A wire 23 is formed on the release layer 22, and a wire 25 is formed on the release layer 24. A via 27 is formed through the insulating material 21 to connect the wires 23 and 25 on the respective opposite surfaces of the insulating material 21 together. The insulating materials 21 and 11 are bonded together with the insulating material 31 interposed between the insulating materials 21 and 11. A via 41 is formed through the insulating materials 11, 21, and 31 to connect the wire 23 formed on the insulating material 21 to the wire 15 formed on the insulating material 11. An electronic device may be mounted on the surface of the wiring substrate 2 or inside the wiring substrate 2.

The wiring substrate 2 shown in FIG. 5 includes the insulating material (first insulating material) 11, the wire 13 formed on the insulating material 11, the insulating material (second insulating material) 31 stacked on the insulating material 11 and the wire 13, and the release layer 12 formed between the insulating material 11 and the wire 13 and containing metal carbonate or metal hydrogen carbonate.

The insulating materials 11, 21, and 31 are formed of, for example, a resin insulating material or an inorganic insulating material. Any of the examples of the material of the insulating material 11 previously disclosed may be used as the insulating materials 11, 21, and 31. Furthermore, the release layers 12, 14, 22, and may contain metal carbonate or metal hydrogen carbonate, and any of the examples of the metal carbonate or metal hydrogen carbonate previously disclosed may be used as the release layers 12, 14, 22, and 24. Moreover, the wires 13, 15, 23, and 25 may be metal or alloy, and for example, any of the examples of the metal or alloy of the wire 13 disclosed herein may be used as the wires 13, 15, 23, and 25. The electronic device mounted on the surface of the wiring substrate 2 or inside the wiring substrate 2, for example, may be similar to the electronic devices previously disclosed herein.

Now, a method for manufacturing the above-described wiring substrate will be described with reference to FIG. 6 through FIG. 11. First, release layers 12 and 14 are formed on the respective opposite surfaces of the insulating material 11. Wires 13 and 15 are formed on the release layers 12 and 14, respectively. A method for forming the release layers and wires may be as previously described.

Then, a via hole 16 is formed in the insulating material 11 as shown in FIG. 6. Examples of a method for forming the via hole 16 include a processing method using a drill, a processing method using a laser, and a processing method using a lithography technique and an etching technique.

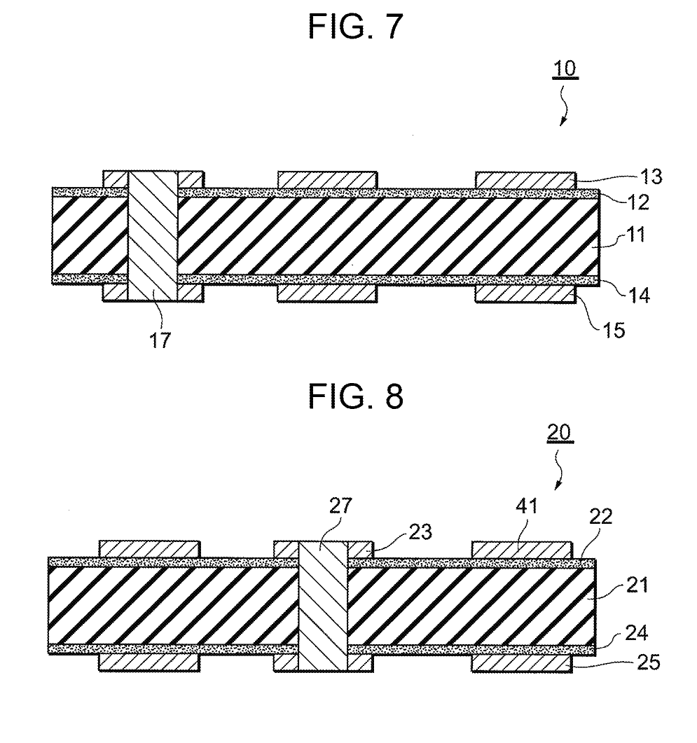

Then, as shown in FIG. 7, the via hole 16 is filled with a conductor to form a via 17. To embed the conductor, electroless plating or conductor paste may be used. Thus, a base material 10 is formed which includes the insulating material 11, the wires 13 and 15 formed on the respective opposite sides of the insulating material via the release layers 12 and 14, and the via 17 penetrating the insulating material 11.

Then, as shown in FIG. 8, a base material 20 is formed which includes an insulating material 21, wires 23 and 25 formed on the respective opposite surfaces of the insulating material 21 via the release layers 22 and 24, and a via 27 penetrating the insulating material 21. The base material 20 is formed in the same manner as that in which the base material 10 is formed.

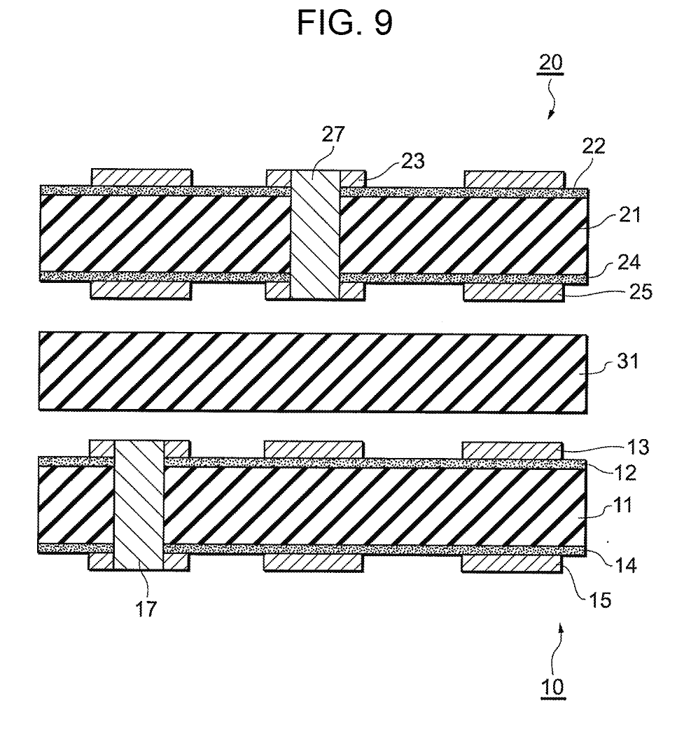

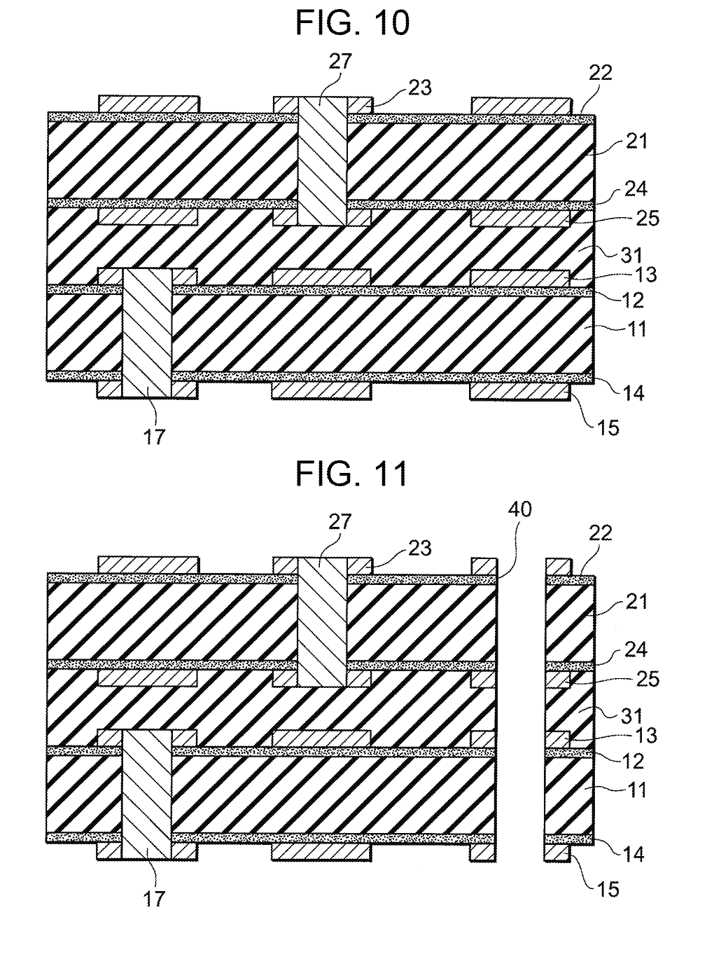

Then, as shown in FIG. 9, the two base materials 10 and 20 are thermocompression-bonded together with the insulating material 31 interposed between the base materials 10 and 20. Thus, as shown in FIG. 10, a structure is formed in which the insulating materials 31 and 21 are stacked on the insulating material 11. For example, a prepreg including a glass cloth impregnated with an epoxy resin may be used as the insulating material 31. The thermocompression bonding allows the semi-cured prepreg to be fully cured. Hence, the two base materials 10 and 20 adhere firmly to each other.

Then, as shown in FIG. 11, a via hole 40 is formed so as to penetrate the insulating materials 11, 21, and 31. Examples of a method for forming the via hole 40 include a processing method using a drill, a processing method using a laser, and a processing method using the lithography technique and the etching technique.

Then, the via hole 40 is filled with a conductor to form a via 41 (see FIG. 5). To embed the conductor, electroless plating or conductor paste may be used. Thus, the via 41 is formed to connect the wire 23 on one side of the wiring substrate 2 to the wire 15 on the other side of the wiring substrate 2.

An electronic device such as an IC chip is mounted, for example, on the surface of the wiring substrate 2. The electronic device is mounted by the same method as described herein.

When the multilayer wiring substrate 2 according to some embodiments disclosed herein is heated to a temperature equal to or higher than the thermal decomposition temperature of the metal carbonate or metal hydrogen carbonate contained in the release layers 12, 14, 22, and 24, (e.g., when the multilayer wiring substrate has been used an is ready for disassembly or recycling), the metal carbonate or metal hydrogen carbonate is thermally decomposed to generate carbon dioxide. Thus, a gas space is interposed between the insulating material and each of the wires 13 and 15 and between the insulating material 21 and each of the wires 23 and 25. This allows the strength of the adhesion of the wires 13, 15, 23, and 25 to the insulating materials 11 and 21 to be sharply reduced. As a result, the wire can be easily released from the insulating material.

As described above, in the wring substrate according to the present embodiment, the presence of the release layer containing the metal carbonate or metal hydrogen carbonate contributes to increasing the efficiency of a metal recovery treatment in the recycling or disposal of the multilayer wiring substrate. Furthermore, is some embodiments, a wiring substrate can be provided which is excellent in economy, safety, and heat resistance.

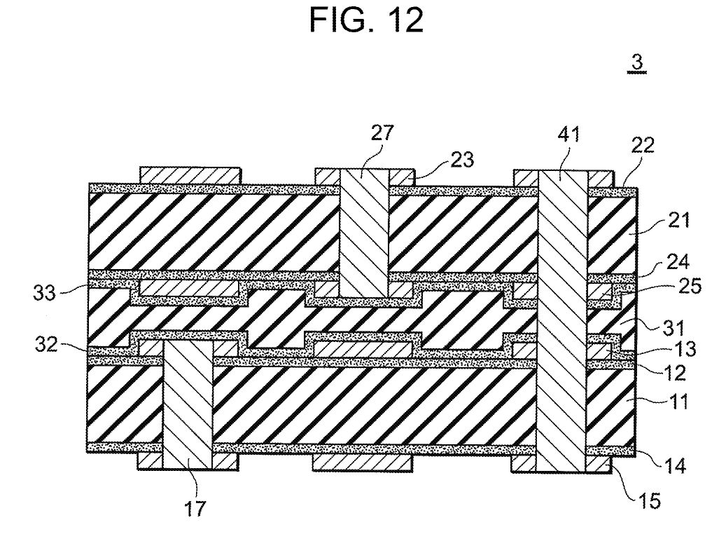

FIG. 12 is a sectional view showing a wiring substrate 3 according to an embodiment. The wiring substrate 3 can be a variation of the wiring substrate 2. The wiring substrate 3 according to this embodiment is the same as the wiring substrate 2 except that a release layer 32 is formed between a wire 13 and an insulating material 31 and that a release layer 33 is formed between a wire 25 and an insulating material 31.

Insulating materials 11, 21, and 31 are formed of, for example, a resin insulating material or an inorganic insulating material. Any of the examples of the resin insulating material or inorganic insulating material disclosed herein may be used as the insulating materials 11, 21, and 31. Furthermore, release layers 12, 14, 22, 24, 32, and 33 may contain metal carbonate or metal hydrogen carbonate, and any of the examples of the metal carbonate or metal hydrogen carbonate disclosed herein may be used as the release layers 12, 14, 22, 24, 32, and 33. Moreover, wires 13, 15, 23, and 25 may be metal or alloy. For example, any of the examples of the metal or alloy disclosed herein may be used. The electronic device mounted on the surface of the wiring substrate 3 or inside the wiring substrate 3, for example, may be similar to or the same as the electronic devices previously disclosed herein.

A method for manufacturing the above-described wiring substrate is the same as the manufacturing method disclosed herein with respect to the wiring substrate 2 except that in the step shown in FIG. 9, the release layers 32 and 33 are preformed on the respective opposite surfaces of the insulating material 31. A method for forming the release layers may be the one described previously.

When the multilayer wiring substrate 3 according embodiments of the disclosure is heated to a temperature equal to or higher than the thermal decomposition temperature of the metal carbonate or metal hydrogen carbonate contained in the release layers 12, 14, 22, 24, 32, and 33 after use, the metal carbonate or metal hydrogen carbonate is thermally decomposed to generate carbon dioxide. Thus, a gas space is interposed between the insulating material 11 and each of the wires 13 and 15, between the insulating material 21 and each of the wires 23 and 25, and between the insulating material 31 and each of the wires 13 and 25. This allows the strength of the adhesion of the wires 13, 15, 23, and 25 to the insulating materials 11, 21, and 31 to be sharply reduced. As a result, the wire can be easily released from the insulating material.

As described above, in the wring substrate according to embodiments of the disclosure, the presence of the release layer containing the metal carbonate or metal hydrogen carbonate contributes to increasing the efficiency of a metal recovery treatment in the recycling or disposal of the multilayer wiring substrate. Furthermore, as previously described, a wiring substrate can be provided which is excellent in economy, safety, and heat resistance.

As described above, embodiments of the disclosure are not limited to the above-described embodiments. Many variations may be made to the embodiments without departing from the spirit of the present disclosure. For example, in the description of the wiring substrate 3, the release layers 12 and 32 are formed between the insulating material (first insulating material) 11 and the wire 13 and between the insulating material (second insulating material) 31 and the wire 13, respectively. However, the release layer may be formed only between the insulating material 11 and the wire 13 or between the insulating material 31 and the wire 13. This also applies to the release layers 24 and 33 between the insulating materials 21 and 31. Those skilled in the art will appreciate that substantially all alternative words or phrases presenting a plurality of selective terms are intended to indicate the possibility of including any one of the terms, either of the terms, or both terms regardless of whether the words or phrases appear in the specification, the claims, or the drawings. For example, the phrase “A or B” includes the possibility of “A”, “B”, or “A and B”.

The wiring substrate according to embodiments of the present disclosure can be utilized for almost all electronic equipment. Examples of the electronic equipment to which the wiring substrate according to the present disclosure is applicable include a mobile phone, an IC card, a liquid crystal display, a plasma display, a car navigation, a game machine, a digital camera, a DVD player, a CD player, a electronic notebook, an electronic dictionary, a personal computer, a personal digital assistant, a video camera, and a printer.

What is claimed is:

1. A wiring substrate comprising:
a first insulating material;
a wire formed on the first insulating material;
a second insulating material stacked on the first insulating material and the wire; and
a release layer formed between the first insulating material and the wire or between the second insulating material and the wire, the release layer configured to release the wire from the first insulating material or the second insulating material after use of the wiring substrate.

2. The wiring substrate of claim 1, wherein the release layer comprises metal carbonate.

3. The wiring substrate of claim 2, wherein the metal carbonate is formed of magnesium carbonate, thallium carbonate, silver carbonate, copper carbonate, lead carbonate, zinc carbonate, iron carbonate, or cobalt carbonate.

4. The wiring substrate of claim 1, wherein the release layer comprises metal hydrogen carbonate.

5. The wiring substrate of claim 4, wherein the metal hydrogen carbonate is formed of sodium hydrogen carbonate or potassium hydrogen carbonate.

6. The wiring substrate of claim 1, wherein the release layer is formed between the first insulating material and the wire and between the second insulating material and the wire.

7. The wiring substrate of claim 1, wherein the release layer generates a gas at a thermal decomposition temperature to reduce a strength of adhesion between the wire and the first insulating layer or the second insulating layer.

8. The wiring substrate of claim 1, wherein the release layer thermally decomposes at a thermal decomposition temperature to release the wire from the first insulating layer or the second insulating layer during disassembly or recycling.

9. A wiring substrate comprising:
an insulating material;
a wire formed on the insulating material; and
a release layer formed between the insulating material and the wire and containing metal carbonate or metal hydrogen carbonate.

10. The wiring substrate of claim 9, wherein the metal carbonate comprises one of magnesium carbonate, thallium carbonate, silver carbonate, copper carbonate, lead carbonate, zinc carbonate, iron carbonate, or cobalt carbonate.

11. The wiring substrate of claim 9, wherein the metal hydrogen carbonate comprises sodium hydrogen carbonate or potassium hydrogen carbonate.

12. The wiring substrate of claim 9, wherein the release layer generates a gas at a thermal decomposition temperature to reduce a strength of adhesion between the wire and the first insulating layer or the second insulating layer.

13. A wiring substrate comprising:
a first insulating material;
a wire formed on the first insulating material;
a second insulating material stacked on the first insulating material and the wire; and
a release layer formed between the first insulating material and the wire or between the second insulating material and the wire, the release layer containing metal carbonate or metal hydrogen carbonate.

14. The wiring substrate of claim 13, wherein the metal carbonate comprises magnesium carbonate, thallium carbonate, silver carbonate, copper carbonate, lead carbonate, zinc carbonate, iron carbonate, or cobalt carbonate.

15. The wiring substrate of claim 13, wherein the metal hydrogen carbonate comprises sodium hydrogen carbonate or potassium hydrogen carbonate.

16. A method for manufacturing a wiring substrate, the method comprising:
forming a release layer containing metal carbonate or metal hydrogen carbonate, on an insulating material; and
forming a wire on the release layer.

17. The method of claim 16, wherein forming the a release layer comprises coating the insulating material with the metal carbonate or metal hydrogen carbonate.

18. The method of claim 16, wherein forming a wire comprises one of forming the wire in an additive method or forming the wire in a subtractive method.

19. A method for disassembling a wiring substrate, the method comprising:
thermally treating a wiring substrate comprising an insulating material, a wire formed on the insulating material, and a release layer formed between the insulating material and the wire and containing metal carbonate or metal hydrogen carbonate, to thermally decompose the release layer; and
releasing the wire from the insulating material.

20. The method of claim 19, further comprising thermally treating the wiring substrate to a decomposition temperature, wherein the release layer generates a gas at the decomposition temperature to reduce a strength of adhesion between the wire and the insulating material.
